(19) United States
(12) Patent Application Publication
(10) Pub. No.: US 2026/0016525 A1
(43) Pub. Date: Jan. 15, 2026

(54) DEVICE AND METHOD FOR TESTING CHARACTERISTICS OF BARE CHIPS

(71) Applicant: Keysight Technologies, Inc., Santa Rosa, CA (US)

(72) Inventors: Yu Watanabe, Hachioji (JP); Takamasa Arai, Hachioji (JP); Ryo Takeda, Hachioji (JP)

(21) Appl. No.: 18/771,836

(22) Filed: Jul. 12, 2024

(51) Int. Cl. G01R 31/26

(52) U.S. Cl. CPC G01R 31/2621

(57) ABSTRACT

A device for testing characteristics of a first bare chip includes a main PCB including a main circuit; a first interposer arranged on the main PCB; a second interposer arranged over the first interposer and the main PCB, where the first and second bare chips are arranged between the first and second interposers for testing the first bare chip; and at least one pressing plate configured to apply a pressing force against the second interposer for pressing the second interposer toward the first interposer and the main PCB. The first interposer provides first electrical connections with the first and second bare chips and the main circuit by contact without soldering, and the second interposer is configured to provide second electrical connections with the first and second bare chips and the main circuit by contact without soldering. The pressing force enhances the first and second electrical connections during the testing.

### BACKGROUND

Wide bandgap (WBG) power devices play a pivotal role in enhancing power efficiency and reducing the footprint of power electronics products, such as electric vehicle inverters. Examples of typical WBG power devices include silicon carbide (SiC) metal-oxide-semiconductor field-effect transistors (MOSFETs). Dynamic parameters of the power WBG devices, such as on-time, off-time, and switching loss, for example, clearly demonstrate advantages of the WBG power devices over traditional silicon (Si) based power semiconductors. For example, SiC MOSFETs exhibit significantly lower switching loss (e.g., 70 to 80 percent lower) compared to Si insulated gate bipolar transistors (IGBTs).

Typically, the dynamic parameters are characterized after placing a power semiconductor chip in a package, such as surface mount device (SMD) package or through-hole leaded component package. Semiconductor chips of the WBG power devices are diced from a wafer. The diced semiconductor chips may be referred to as “bare chips” or “bare dies.” The dynamic parameter characterization directly on a power semiconductor chip is extremely difficult. Efficient and accurate dynamic methods for testing bare chips, which are extremely small and delicate, have not been developed for a number of practical reasons, examples of which are discussed below.

First, testing bare chips requires time-consuming packaging and assembling. That is, bare chips are tested using some sort of contact technology, such as complete packages created similarly to commercial SMDs, or temporary packages fabricated for specific testing by soldering wires (wire-bonding) between the bare chips and test boards. A special facility is needed to create the complete packages, the production of which takes a month or more. Fabricating the temporary packages is intricate work that still requires a wire-bonder and may take a week or more to complete. This poses a significant hurdle for researchers seeking accelerated development of WBG power devices.

Second, the WBG power devices being tested must be soldered to a test circuit. That is, both the complete packages and the temporary packages involve soldering the WBG devices to the test circuit. The soldering, however, makes it difficult to change out the DUTs when testing multiple samples is required.

Third, the samples of the WBG power devices being tested are physically damaged. That is, soldering and desoldering the bare chips to and from the test circuit during the testing wears them out, rendering them unsuitable for sale. Likewise, alternative contact methods that do not include soldering, such as using probes, pins, or needles to establish electrical contact, result in scratches or dents on bare chips, which also ruins or devalues them for commercial purposes.

Fourth, achieving an accurate, reliable evaluation is difficult. WBG power devices exhibit significantly faster switching than Si power devices, for example, resulting in voltage change (dv/dt) and current change (di/dt) values that are about ten times higher than those of Si power devices. This high-speed switching behavior amplifies the impact of even minor parasitic inductance in the test circuit, causing critical failures, such as false turn-on, oscillation, and device destruction. Also, due to the vertical structure common in most SiC chips, featuring gate and source electrodes on one side and a drain electrode on the opposite side, all contact technologies typically involve relatively lengthy wiring. When using a probe, the probe needle itself exhibits a large extra stray inductance. As a result, existing measurement methods introduce significant parasitic inductance, which compromises the quality of dynamic tests and occasionally leads to notable failures, including breakdown of the power device being tested.

### BRIEF DESCRIPTION OF THE DRAWINGS

The example embodiments are best understood from the following detailed description when read with the accompanying drawing figures. It is emphasized that the various features are not necessarily drawn to scale. In fact, the dimensions may be arbitrarily increased or decreased for clarity of discussion. Wherever applicable and practical, like reference numerals refer to like elements.

FIG. 1 is a simplified cross-sectional view of a device for testing characteristics of a bare chip as a device under test (DUT), according to a representative embodiment.

FIG. 2 is a simplified circuit diagram of dynamic test circuit including the device for testing characteristics of a bare chip, according to a representative embodiment.

FIG. 3A is a perspective view of a test fixture including the device for testing characteristics of a bare chip, according to a representative embodiment.

FIG. 3B is a perspective view of a test fixture including the device for testing characteristics of a bare chip and a pressing force assembly, according to a representative embodiment.

FIG. 4 is a flow diagram showing a method for testing a bare chip as a DUT, according to a representative embodiment.

### DETAILED DESCRIPTION

In the following detailed description, for purposes of explanation and not limitation, representative embodiments disclosing specific details are set forth in order to provide a thorough understanding of an embodiment according to the present teachings. Descriptions of known systems, devices, materials, methods of operation and methods of manufacture may be omitted so as to avoid obscuring the description of the representative embodiments. Nonetheless, systems, devices, materials and methods that are within the purview of one of ordinary skill in the art are within the scope of the present teachings and may be used in accordance with the representative embodiments. It is to be understood that the terminology used herein is for purposes of describing particular embodiments only and is not intended to be limiting. The defined terms are in addition to the technical and scientific meanings of the defined terms as commonly understood and accepted in the technical field of the present teachings.

It will be understood that, although the terms first, second, third etc. may be used herein to describe various elements or components, these elements or components should not be limited by these terms. These terms are only used to distinguish one element or component from another element or component. Thus, a first element or component discussed below could be termed a second element or component without departing from the teachings of the present disclosure.

The terminology used herein is for purposes of describing particular embodiments only and is not intended to be limiting. As used in the specification and appended claims, the singular forms of terms “a,” “an” and “the” are intended to include both singular and plural forms, unless the context clearly dictates otherwise. Additionally, the terms “comprises,” and/or “comprising,” and/or similar terms when used in this specification, specify the presence of stated features, elements, and/or components, but do not preclude the presence or addition of one or more other features, elements, components, and/or groups thereof. As used herein, the term “and/or” includes any and all combinations of one or more of the associated listed items.

Unless otherwise noted, when an element or component is said to be “connected to,” “coupled to,” or “adjacent to” another element or component, it will be understood that the element or component can be directly connected or coupled to the other element or component, or intervening elements or components may be present. That is, these and similar terms encompass cases where one or more intermediate elements or components may be employed to connect two elements or components. However, when an element or component is said to be “directly connected” to another element or component, this encompasses only cases where the two elements or components are connected to each other without any intermediate or intervening elements or components.

Relative terms, such as “above,” “below,” “top,” “bottom,” “upper” and “lower” may be used to describe the various elements' relationships to one another, as illustrated in the accompanying drawings. These relative terms are intended to encompass different orientations of the device and/or elements in addition to the orientation depicted in the drawings. For example, if the device were inverted with respect to the view in the drawings, an element described as “above” another element, for example, would now be “below” that element. Similarly, if the device were rotated by 90 degrees with respect to the view in the drawings, an element described “above” or “below” another element would now be “adjacent” to the other element; where “adjacent” means either abutting the other element, or having one or more layers, materials, structures, etc., between the elements.

The present disclosure, through one or more of its various aspects, embodiments and/or specific features or sub-components, is thus intended to bring out one or more of the advantages as specifically noted below. For purposes of explanation and not limitation, example embodiments disclosing specific details are set forth in order to provide a thorough understanding of an embodiment according to the present teachings. However, other embodiments consistent with the present disclosure that depart from specific details disclosed herein remain within the scope of the appended claims. Moreover, descriptions of well-known apparatuses and methods may be omitted so as to not obscure the description of the example embodiments. Such methods and apparatuses are within the scope of the present disclosure.

Generally, the various embodiments provide a device that includes flexible solderless interposers stacked over a bare chip to be tested, and a mechanism to minimize parasitic inductance during the testing. The embodiments eliminate lengthy preparation required for both complete and temporary packaging used for conventional testing. That is, the embodiments enable testing of bare chips directly, simplifying the measurement process, where the preparation for the test may be done within about five minutes. No soldering is required. Therefore, multiple bare chips may be easily measured sequentially without wearing out the bare chips, as well as the test boards. There is little damage to the bare chips, such as scratches and dents, so that the same bare chips being tested can be used for commercial production. The embodiments also minimize parasitic inductance, and enhance accuracy and reliability of the dynamic testing.

According to a representative embodiment, a device is provided for testing characteristics of a device under test (DUT), including a first bare chip. The device includes a main printed circuit board (PCB) including a main circuit, a first interposer arranged on a surface of the main PCB, a second interposer arranged over the first PCB interposer and the surface of the main PCB, where the first bare chip and a second bare chip are arranged between the second interposer and the first interposer for testing the first bare chip, and pressing plates configured to apply a pressing force against the second interposer for pressing the second interposer toward the first interposer and the main PCB. The first interposer is configured to provide first electrical connections with the first bare chip, the second bare chip, and the main circuit by contact during the testing, without soldering. The second interposer is configured to provide second electrical connections with the first bare chip, the second bare chip, and the main circuit by contact during the testing, without soldering. The pressing force applied by the pressing plates enhances the first and second electrical connections during the testing of the first bare chip. The device may further include alignment pins configured to align the main PCB, the first interposer, and the second interposer for the testing, while enabling the second interposer to move vertically relative to the first interposer to accommodate a thickness of the low-side power device and the high-side power device.

According to another representative embodiment, a device is provided for testing characteristics of a DUT, the DUT being a first bare chip. The device includes a main PCB including a main circuit; a first interposer arranged on a surface of the main PCB; a second interposer arranged over the first interposer and the surface of the main PCB, where the first bare chip is arranged between the second interposer and the first interposer in a first orientation for testing of the first bare chip, and a second bare chip is arranged between the second interposer and the first interposer in a second orientation for the testing of the first bare chip, where the second orientation is opposite the first orientation; and at least one pressing plate configured to apply a pressing force against the second interposer for pressing the second interposer toward the first interposer and the main PCB to enhance electrical connections between each of the first and second bare chips and the first interposer, between each of the first and second bare chips and the second interposer, and between each of the first and second interposers and the main PCB.

According to another representative embodiment, a method is provided for testing a DUT. The method includes arranging a first interposer on a surface of a main PCB including a main circuit; arranging a first bare chip and a second bare chip on a surface of the first interposer, wherein the first bare chip is the DUT, and where the first interposer provides first electrical connections with the first bare chip, the second bare chip, and the main circuit by contact, without soldering; arranging a second interposer arranged over the first bare chip, the second bare chip, the first interposer and the main PCB, such that the first bare chip and a second bare chip are between the second interposer and the first interposer for testing of the first bare chip, where the second interposer is configured to provide second electrical connections with the first bare chip, the second bare chip, and the main circuit by contact, without soldering; arranging at least one pressing plate on at least one portion of the second interposer; applying a pressing force against the at least one pressing plate for pressing the second interposer toward the first interposer and the main PCB, where the pressing force enhances the first and second electrical connections; and testing at least one characteristic of the first bare chip while applying the pressing force against the second interposer.

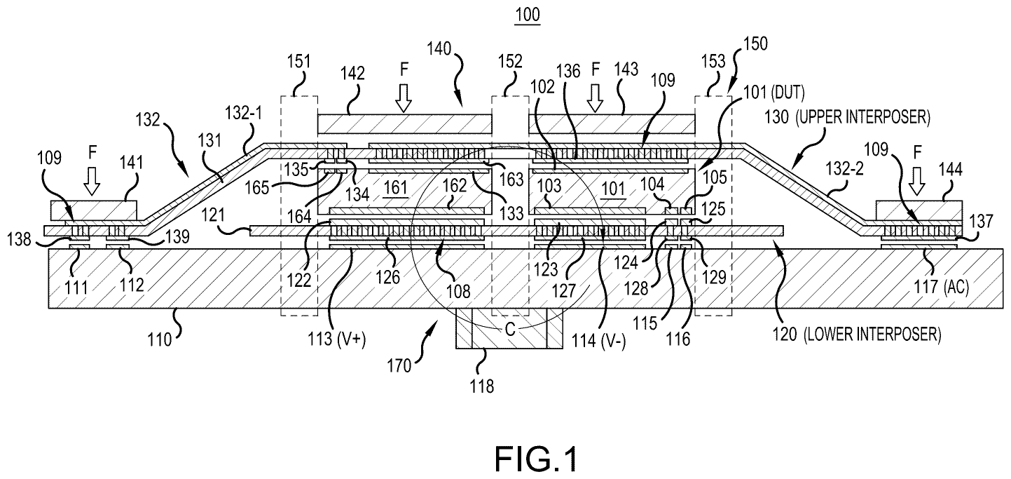

FIG. 1 is a simplified cross-sectional view of a device for testing dynamic characteristics of a bare chip, according to a representative embodiment.

Referring to FIG. 1, test device 100 includes a main printed circuit board (PCB) 110, a first interposer 120 arranged on a top surface of the main PCB, and a second interposer 130 arranged over the first interposer 120 and the surface of the main PCB 110. Two bare chips are arranged between the first and second interposers 120 and 130, including a first bare chip 101 and a second bare chip 161. In the depicted embodiment, the first bare chip 101 is the device under test (DUT), which may be a semiconductor WBG power device, such as a SiC MOSFET or a gallium nitride (GaN) FET, for example. Testing a DUT in the form of a bare chip, such as the first bare chip 101, is advantageous over testing an assembled device. For example, by measuring the bare chip, dynamic characteristics of a power semiconductor device can be measured immediately before it is packaged, which takes long time and is expensive, and intrinsic characteristics of the power semiconductor device can be obtained by minimizing effects of parasitic components, such as bonding wire. The second bare chip 161 may be the same type of bare chip as the first bare chip 101, which generally simplifies test setup and performance, although the first and second bare chips 101 and 161 may be different from one another without departing from the scope of the present teachings. For example, the second bare chip 161 may be any of various types of FET functioning as a transistor or as a diode.

The test device 100 further includes a pressing plate arrangement 140 that includes multiple pressing plates, indicated by first pressing plate 141, second pressing plate 142, third pressing plate 143, and fourth pressing plate 144. The first to fourth pressing plates 141 to 144 are configured to apply a pressing force F against respective portions of the second interposer 130 for pressing the second interposer 130 toward the first interposer 120 and the main PCB 110. As discussed further below, the pressing force F applied by the pressing plate arrangement 140 enhances electrical connections between each of the first and second bare chips 101 and 161 and the first interposer 120, between each of the first and second bare chips 101 and 161 and the second interposer 130, and between each of the first and second interposers 120 and 130 and the main PCB during the testing.

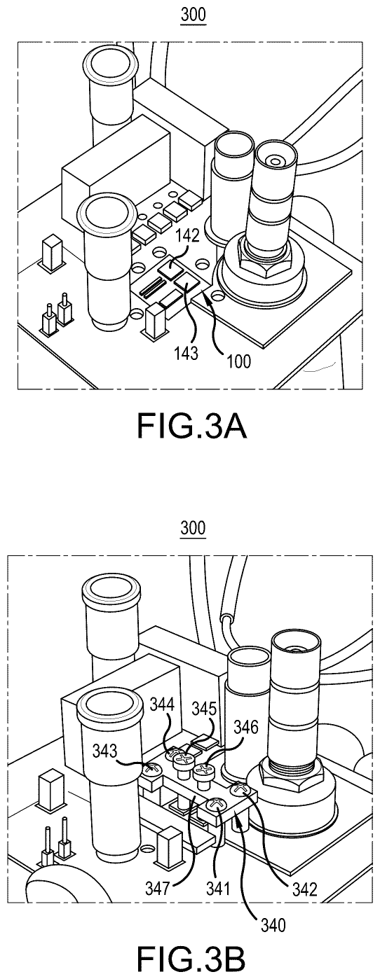

The pressing force F may be applied by manual pressure and/or mechanical fasteners configured to exert a linear force toward the main PCB 110 in a direction substantially vertical to a plane of the main PCB 110. For example, as discussed below with reference to FIGS. 3A and 3B, the pressing plate arrangement 140 may include through holes for screws or bolts that attach to corresponding holes in the main PCB 110 or a platform on which the main PCB 110 is situated. Tightening the screws or bolts moves the pressing plate arrangement 140 in the vertical direction toward the main PCB 110, thereby applying the pressing force F to the first and second interposers 120 and 130. The pressing force F may be in a range of about 2 to about 4 cNm, for example. The bare chips 101 and 161 are fragile, and therefore the pressing force F must be applied carefully. Tightening the screws or bolts may be done using a torque screwdriver or wrench, for example, to assure that the tightening force is in the proper good range.

The test device 100 may also include optional alignment arrangement 150 configured to properly align the main PCB 110, the first interposer 120, and the second interposer 130 in a vertical direction (as shown in FIG. 1) for testing. In the depicted example, the alignment arrangement 150 has multiple alignment pins, indicated by first alignment pin 151 along an edge of the second bare chip 161, second alignment pin 152 between the first and second bare chips 101 and 161, and third alignment pin 153 along an edge of the first bare chip 101. The first through third alignment pins 151 to 153 may be slidable through respective holes in the main PCB 110, the first interposer 120, and the second interposer 130, respectively, such that the first interposer 120 and the second interposer 130 are movable relative to one another in a vertical direction. This accommodates thicknesses of the first and second bare chips 101 and 161, and enables the first interposer 120 and the second interposer 130 to be movable relative to the main PCB 110, for example, in response to the pressing force applied by the first through fourth pressing plates 141 to 144 to enhance the electrical connections, as discussed above.

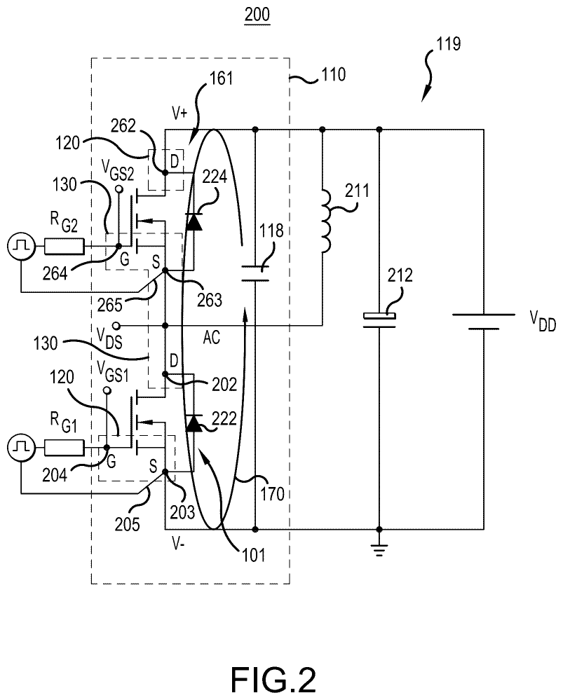

The main PCB 110 includes a rigid or flexible substrate of insulating material and electrical circuitry formed in and on the substrate. The substrate may be formed in layers of insulating material, and the electrical circuitry may be formed of as layers and/or traces of electrically conductive material on and between the layers of insulating material. The insulating material of the substrate may be any compatible insulating and/or dielectric material, such as polytetrafluoro-ethylene (Teflon), FR-1, FR-2, FR-3, FR-4, FR-5, FR-6, CEM-1, CEM-2, CEM-3 CEM-4 or CEM-5, for example. The electrically conductive material may be any compatible conductor, such as copper, aluminum, gold, or silver, for example. The main PCB 110 includes a main circuit 119 of electrical contacts and traces formed by the electrically conductive material, and components (e.g., decoupling capacitor 118) configured to enable testing of the first bare chip 101. An example of the main circuit 119 and connections with the first and second bare chips 101 and 161 is discussed below with reference to FIG. 2.

Each of the first interposer 120 and the second interposer 130 also may be a PCB. The first interposer 120 includes a thin flexible first substrate 121 of insulating material, and electrical circuitry formed in and on the first substrate 121. The second interposer 130 includes a thin flexible second substrate 131 of insulating material, and electrical circuitry formed in and on the second substrate 131. Each of the first and second substrates 121 and 131 may have a thickness of about 0.008 inch to about 0.012 inch, for example. Due in part to flexibility, the second interposer 130 is able to bend and connect to the main PCB 110 easily, while also absorbing the thickness of each of the first and second bare chips 101 and 161. The insulating material of the first and second substrates 121 and 131 may be any compatible insulating and/or dielectric material, such as Kapton film, for example. The electrical circuitry is formed of any compatible electrically conductive material, such as copper, aluminum, gold, or silver, for example. The first interposer 120 provides first electrical connections between the first and second bare chips 101 and 161 and the main circuit 119, and the second interposer 130 provides second electrical connections between the first and second bare chips 101 and 161 and the main circuit 119, as discussed below. Because of the pressing force F applied by the first to fourth pressing plates 141 to 144, the first and second electrical connections are provided without soldering or other physical attachment.

As mentioned above, each of the first and second bare chip 101 and 161 may be a FET, such as SiC MOSFET or a GaN FET, for example, although other types of bare chips may be incorporated without departing from the scope of the present teachings. The first bare chip 101 is arranged in a first orientation, and the second bare chip 161 is arranged in a second orientation that is opposite the first orientation. That is, the same type of electrode facing upward on the first bare chip 101 is facing downward on the second bare chip 161, and vice versa, as described below.

For example, in the depicted embodiment, the first bare chip 101 (i.e., the DUT) includes a first drain electrode 102 on a top surface (i.e., facing the second interposer 130), and a first source electrode 103, a first gate electrode 104, and a first Kelvin source electrode 105 on an opposite, bottom surface (i.e., facing the first interposer 120) of the first bare chip 101. The first drain electrode 102, the first source electrode 103, the first gate electrode 104, and the first Kelvin source electrode 105 correspond to first drain, first source, first gate, and first Kelvin source of the first bare chip 101, respectively, as discussed below with reference to FIG. 2. Similarly, the second bare chip 161 includes a second drain electrode 162 on a bottom surface (i.e., facing the first interposer 120), and a second source electrode 163, a second gate electrode 164, and a second Kelvin source electrode 165 on an opposite, top surface (i.e., facing the second interposer 130) of the second bare chip 161. As such, the second bare chip 161 is arranged in an orientation opposite to that of the first bare chip 101. The second drain electrode 162, the second source electrode 163, the second gate electrode 164, and the second Kelvin source electrode 165 correspond to second drain, second source, second gate, and second Kelvin source of the second bare chip 161, respectively, as discussed below with reference to FIG. 2.

The first and second bare chips 101 and 161 electrically connect to the main circuit 119 of the main PCB 110 through a set of corresponding contacts of the first and second interposers 120 and 130, where contacts may refer to contact pads or landings, for example. In particular, in the depicted embodiment, the first interposer 120 includes multiple inner contacts (i.e., facing toward the bare chips) on the first substrate 121 for establishing electrical connections to the electrodes of the first and second bare chips 101 and 161, and multiple outer contacts (i.e., facing away from the bare chips) on the opposite side of the first substrate 121 for establishing electrical connections to contacts in the main PCB 110. That is, the first interposer 120 includes an inner first source contact 123 for contacting the first source electrode 103, an inner first gate contact 124 for contacting the first gate electrode 104, and an inner first Kelvin source contact 125 for contacting the first Kelvin source electrode 105 of the first bare chip 101, and an inner second drain contact 122 for contacting the second drain electrode 162 of the second bare chip 161. On the opposite side, the first interposer 120 further includes an outer first source contact 127 for contacting a PCB negative voltage (V−) contact 114, an outer first gate contact 128 for contacting a PCB first gate contact 115, and an outer first Kelvin source contact 129 for contacting a PCB first Kelvin source contact 116 of the main PCB 110, and a PCB outer second drain contact 126 for contacting a PCB positive voltage (V+) contact 113 in the main circuit 110.

Since the inner and outer contacts of the first interposer 120 are on opposite sides, the first interposer 120 also includes through-vias, collectively indicated as through-vias 108, for connecting corresponding contacts through the first interposer 120. That is, the through-vias 108 are configured to connect the inner first source contact 123 to the outer first source contact 127, the inner first gate contact 124 to the outer first gate contact 128, the inner first Kelvin source contact 125 to the outer first Kelvin source contact 129, and the inner second drain contact 122 to the outer second drain contact 126 through the first interposer 120.

Accordingly, by way of the various contacts and connections described above, the first source electrode 103 of the first bare chip 101 is electrically connected to the PCB negative voltage (V−) contact 114 of the main PCB 110, the first gate electrode 104 is electrically connected to the PCB first gate contact 115, the first Kelvin source electrode 105 is electrically connected to the PCB first Kelvin source contact 116, and the second drain electrode 162 of the second bare chip 161 is electrically connected to the PCB positive voltage (V+) contact 113. Application of the pressing force F by the pressing plate arrangement 140 enhances each of these electrical connections during the testing.

The second interposer 130 also includes multiple inner contacts (i.e., facing toward the bare chips) on the second substrate 131 for establishing electrical connections to the electrodes of the first and second bare chips 101 and 161, as well as for connecting to contacts on the main PCB 110. That is, the second interposer 130 includes an inner second source contact 133 for contacting the second source electrode 163, an inner second gate contact 134 for contacting the second gate electrode 164, and an inner second Kelvin source contact 135 for contacting the second Kelvin source electrode 165 of the second bare chip 161, and an inner first drain contact 136 for contacting the first drain electrode 102 of the first bare chip 101. The second interposer 130 also includes an end first drain contact 137 for contacting PCB AC voltage contact 117 on the main PCB 110 at one end of the second interposer 130, and an end second gate contact 138 and an end second Kelvin source contact 139 for contacting a PCB second gate contact 111 and a PCB second Kelvin source contact 112 on the main PCB 110 at the opposite end of the second interposer 130.

On the opposite side, the second interposer 130 has outer conductors 132 on the outer surface (i.e., facing away from the bare chips) of the second interposer 130. In the depicted embodiment, the outer conductors 132 include an outer first conductor 132-1 and an outer second conductor 132-2. In this configuration, the substrate 131 of the second interposer 130 acts as an insulator and thus enhances insulation voltage between the outer conductors 131, the first and second bare chips 101 and 161, and the main PCB 110, avoiding spark and arching between them.

The second interposer 130 also includes through-vias, collectively indicated as through-vias 109, for connecting corresponding contacts through the substrate 131 of the second interposer 130. That is, the through-vias 109 are configured to connect the inner second gate contact 134 and the inner second Kelvin source contact 135 to the first outer conductor 132-1, and to connect the inner second source contact 163 and the inner first drain contact 136 to the second outer conductor 132-2. At the far ends of the second interposer 130, the through-vias 109 are also configured to connect the end second gate contact 138 and the end second Kelvin source contact 139 to the first outer conductor 132-1, and to connect the end first drain contact 137 to the second outer conductor 132-2.

Accordingly, by way of the various contacts and connections described above, the first drain electrode 102 of the first bare chip 101 and the second source electrode 163 of the second bare chip 161 are electrically connected to the PCB AC voltage contact 117 of the main PCB 110, and second gate electrode 164 and the second Kelvin source electrode 165 are electrically connected to the PCB second gate contact 111 and the PCB second Kelvin source contact 112 on the main PCB 110, respectively. Application of the pressing force F by the pressing plate arrangement 140 enhances each of these electrical connections during the testing. Also, connecting the second interposer 130 to both of the first and second bare chips 101 and 161 simplifies the structure of the test device 100 and minimizes power loop inductance, indicated by arrow 170.

Because there is not soldering or other mechanical attachment of the first bare chip 101 (or the second base chip 161) to the first and second interposers 120 and 130, the testing device 100 can be assembled for testing the first bare chip 101 and disassembly following the testing of the first bare chip 101 very quickly and efficiently. Also, no packing of the first bare chip 101 is required for the testing. Also, without soldering or other mechanical attachment, and without prodding by external probes, the first bare chip is not damaged or worn out (e.g., from denting and/or scratching) during the testing process, so that it is still suitable for additional use or sale.

FIG. 2 is a simplified circuit diagram of dynamic test circuit including the device for testing characteristics of a bare chip, according to a representative embodiment. Components in the circuit diagram are labeled with like reference numbers of corresponding components in the device of FIG. 1.

Referring to FIG. 2, circuit 200 includes main circuit 119 of the main PCB 110 connected to first bare chip 101 and second bare chip 161. The main circuit 119 includes the decoupling capacitor 118, inputs for drain-source voltage VDs, first gate-source voltage V_{GS1}, second gate-source voltage V_{GS2}, and conductors for electrically connecting to the electrodes of the first and second bare chips 101 and 161. The main circuit 119 also includes a load inductor 211, a bank capacitor 212, and a power supply V_{DD}, discussed below.

The first interposer 120 and the second interposer 130 are indicated by dashed lines at locations where they contact corresponding electrodes of the first and second bare chips 101 and 161, respectively. Each of the first and second bare chips 101 and 161 is shown as an FET, for example. The first bare chip 101 (i.e., the DUT) includes first drain 202 (corresponding to the first drain electrode 102) connected to the AC voltage provided at drain-source voltage source VDS in the second interposer 130, first source 203 (corresponding to the first source electrode 103) connected to negative voltage V− at the low side of the power supply V_{DD} in the first interposer 120, first gate 204 (corresponding to the first gate electrode 104) connected to the first gate-source voltage V_{GS1} and first gate resistor R_{G1}, and first Kelvin source 205 (corresponding to the first Kelvin source electrode 105) connected between the first gate 204 and the first source 203. A first diode 222 is shown connected between the first source 203 and the first drain 202.

The second bare chip 161 includes second drain 262 (corresponding to the second drain electrode 162) connected to positive voltage V+ at the high side of the power supply V_{DD} in the first interposer 120, second source 263 (corresponding to the second source electrode 163) connected to the AC voltage in the second interposer 130, second gate 264 (corresponding to the second gate electrode 164) connected to the second gate-source voltage V_{GS2} and second gate resistor R_{G2}, and second Klevin source 265 (corresponding to the second Kelvin source electrode 165) connected between the second gate 264 and the second source 263. A second diode 224 is shown connected between the second source 263 and the second drain 262.

In the main circuit 119, the load inductor 211 is connected between the AC voltage and the positive voltage V+ (or the second drain 262 of the second bare chip 161). Each of the decoupling capacitor 118, the bank capacitor 212 and the power supply V_{DD} is connected between the positive voltage V+ (or the second drain 262 of the second bare chip 161) and the negative voltage V−.

Testing the first bare chip 101 may include applying voltage pulses to the first gate 204 of the first bare chip 101 and/or to the second gate 264 of the second bare chip 161 using corresponding gate drivers, depending on the type of test being performed. Therefore, FIG. 2 shows the first gate 204 configured to input voltage pulses from the first gate-source voltage V_{GS1} through the first gate resistor R_{G1}, and the second gate 264 configured to input voltage pulses from the second gate-source voltage V_{GS2} through the second gate resistor R_{G2}. For example, in order to characterize switching time/energy parameters of the first bare chip 101, such as delay time Td (on/off), turn-on time Tr/turn-off time Tf, and turn-on loss Eon/turn-off loss Eoff, a double pulse test sequence is applied to the first gate 204 in order to switch the first bare chip 101 on and off, while 0 or negative voltage is applied to the second gate 264 of the second bare chip 161 to keep the second bare chip 161 turned off. As another example, in order to test reverse recovery characteristics of the first bare chip 101, such as reverse recovery current IRR, reverse recovery charge QRR, and reverse recovery time tRR, a pulse test sequence is applied to the second gate 262 in order to switch the second bare chip 161 on and off, while 0 or negative voltage is applied to the first gate 204 of the first bare chip 101 to keep the first bare chip 101 turned off. Of course, the circuit 200 may be used to perform other types of testing of the first bare chip 101 that would benefit from the enhanced electrical connections provided by the pressing plate arrangement without departing from the scope of the present teachings.

FIG. 3A is a perspective view of a test fixture including the device for testing characteristics of a bare chip, and FIG. 3B is a perspective view of a test fixture including the device for testing characteristics of the bare chip and a pressing force assembly, according to a representative embodiment.

Referring to FIG. 3A, a test fixture 300 having a top surface to which the test device 100 is mounted. In the depicted state of assembly, the test device 100 includes the second pressing plate 142, third pressing plate 143 situated over and thus covering the first and second bare chips 101 and 162 (not visible in FIG. 3A).

Referring to FIG. 3B, a pressing force assembly 340 have been placed over the test device 100 and attached to the test fixture 300. The pressing force assembly 340 is configured to apply the pressing force F to the second and third pressing plates 142 and 143 (not visible in FIG. 3B), which in turn transfer the pressing force F to the first and second interposers 120 and 130, as discussed above. In the depicted embodiment, the pressing force assembly 340 includes a frame 347, which may be formed of any compatible, substantially rigid material, such as plastic or hard rubber or silicon, for example. The frame 347 is physically attached to the test fixture 300 (or alternatively, to the main PCB 110 of the test device 100) by multiple fasteners, indicated by first screw 341, second screw 342, third screw 343, and fourth screw 344, although other types of fasteners may be incorporated without departing from the scope of the present teachings.

The pressing force assembly 340 further includes set screws, indicated by first set screw 345 and second set screw 346. The first and second set screws 345 and 346 pass through corresponding threaded holes in the frame 347, and are configured to apply the downward pressing force F to the second and third pressing plates 142 and 143 upon operation (e.g., as they are manually tightened). Other types of set devices, such as mechanical clamps with spring assist, for example, may be incorporated without departing from the scope of the present teachings. Also, automated tightening devices may be incorporated, such as pins or rods controlled automatically by server motors, pneumatics or hydraulics, for example, to apply the pressing force F at a predetermined magnitude set by a controller.

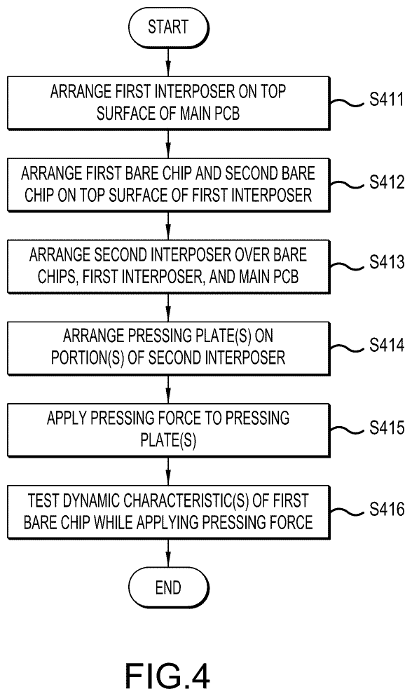

FIG. 4 is a flow diagram showing a method for testing a bare chip as a DUT, according to a representative embodiment. The method of FIG. 4 may be implemented using embodiments of the device discussed above with reference to FIGS. 1-3B, for example.

Referring to FIG. 4, a first interposer is arranged on a top surface of a main PCB of a testing device in block S411, where the main PCB includes a main circuit configured to enable testing of the DUT. The main PCB itself may be previously fixed to a test fixture. The first interposer is arranged in a predetermined position on the main PCB so that contacts on a bottom surface of the first interposer are aligned and in physical contact with corresponding PCB contacts the top surface of the main PCB.

In block S412, a first bare chip and a second bare chip are arranged on a top surface of the first interposer, where the first bare chip is the DUT. The first and second bare chips are arranged in predetermined positions on the first interposer such that at least one first electrode of the first bare chip and at least one second electrode of the second bare chip are aligned and in physical contact with corresponding contacts on a top surface of the first interposer. The first interposer thus provides first electrical connections with the first bare chip, the second bare chip, and the main circuit by contact, without soldering. The first bare chip may be arranged in a first orientation and the second bare chip may be arranged in a second orientation that is opposite the first orientation, in which case the same type of electrode facing upward on the first bare chip is facing downward on the second bare chip, and vice versa.

In block S413, a second interposer is arranged over the first bare chip, the second bare chip, the first interposer and the main PCB, such that the first bare chip and a second bare chip are between the second interposer and the first interposer for the testing of the first bare chip. The second interposer is arranged in a predetermined position over the first and second bare chips such that at least one first electrode of the first bare chip and at least one second electrode of the second bare chip are aligned and in physical contact with corresponding contacts on a bottom surface of the second interposer. The second interposer is also arranged in a predetermined position over the main PCB so that contacts on a bottom surface of the second interposer are aligned and in physical contact with corresponding PCB contacts the top surface of the main PCB. The second interposer thus provides second electrical connections with the first bare chip, the second bare chip, and the main circuit by contact, without soldering.

In block S414, at least one pressing plate is arranged on at least one portion of the second interposer. Generally, the pressing plates are arranged over portions of the second interposer where electrodes of the first and second bare chips align with contacts on one or more of the first and second interposers and/or the main PCB, and/or over portions of the second interposer where contacts on one or more of the first and second interposers aligning with contacts on the main PCB.

In block S415, a pressing force is applied to the at least one pressing plate, which translates the pressing force against the second interposer for pressing the second interposer toward the first interposer and the main PCB. The pressing force may be applied by a pressing force assembly to a top surface of the second interposer, for example. The pressing force enhances the first and second electrical connections, without the need for soldering or implementing some other mechanical connection. Accordingly, the first and second bare chips can be easily removed following the testing, e.g., without desoldering or otherwise mechanically detaching the first and second bare chips from the testing device. This speeds up the testing process significantly. Also, as mentioned above, the first bare chip is not damaged or worn out during the testing process, so that it is not devalued, and is otherwise suitable for additional use or sale.

In block S416, at least one dynamic characteristic of the first bare chip is tested while the pressing force is applied against the second interposer. The enhanced first and second electrical connections provided by application of the pressing force increases accuracy of the testing. The test may be any type of bare chip testing, such as characterizing switching time/energy parameters of the first bare chip and characterizing test reverse recovery of the first bare chip, discussed above.

While the invention has been illustrated and described in detail in the drawings and foregoing description, such illustration and description are to be considered illustrative or exemplary and not restrictive; the invention is not limited to the disclosed embodiments. Other variations to the disclosed embodiments can be understood and effected by those having ordinary skill in the art in practicing the claimed invention, from a study of the drawings, the disclosure, and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measures cannot be used to an advantage.

Aspects of the present invention may be embodied as an apparatus, method or computer program product. Accordingly, aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects of the present invention may take the form of a computer program product embodied in one or more computer readable medium(s) having computer executable code embodied thereon.

While representative embodiments are disclosed herein, one of ordinary skill in the art appreciates that many variations that are in accordance with the present teachings are possible and remain within the scope of the appended claim set. The invention therefore is not to be restricted except within the scope of the appended claims.

1. A device for testing characteristics of a device under test (DUT), the DUT being a first bare chip, the device comprising:
a main printed circuit board (PCB) comprising a main circuit;
a first interposer arranged on a surface of the main PCB;
a second interposer arranged over the first interposer and the surface of the main PCB, wherein the first bare chip and a second bare chip are arranged between the second interposer and the first interposer for testing the first bare chip; and
at least one pressing plate configured to apply a pressing force against the second interposer for pressing the second interposer toward the first interposer and the main PCB,
wherein the first interposer is configured to provide first electrical connections with the first bare chip, the second bare chip, and the main circuit by contact during the testing, without soldering,
wherein the second interposer is configured to provide second electrical connections with the first bare chip, the second bare chip, and the main circuit by contact during the testing, without soldering, and
wherein the pressing force applied by the at least one pressing plate enhances the first and second electrical connections during the testing of the first bare chip.

2. The device of claim 1, further comprising:
a plurality of alignment pins configured to align the main PCB, the first interposer, and the second interposer for the testing, while enabling the second interposer to move vertically relative to the first interposer to accommodate a thickness of the first bare chip and the second bare chip.

3. The device of claim 1, wherein each of the first interposer and the second interposer comprises a thin flexible substrate.

4. The device of claim 3, wherein the second interposer includes outer conductors on an outer surface, facing away from the first and second bare chips,
wherein the outer conductors electrically connect the first and second bare chips to the main circuit, and
wherein the thin flexible substrate of the second interposer acts as an insulator and enhances insulation voltage between the outer conductors on the outer surface of the second interposer and each of the first bare chip, the second bare chip, and the main circuit.

5. The device of claim 4, wherein the first interposer comprises an inner first source contact for contacting a first source electrode of the first bare chip, an inner first gate contact for contacting a first gate electrode of the first bare chip, an inner first Kelvin source contact for contacting a first Kelvin source electrode of the first bare chip, and an inner second drain contact for contacting a second drain electrode of the second bare chip; and
wherein the second interposer comprises an inner second source contact for contacting a second source electrode of the second bare chip, an inner second gate contact for contacting a second gate electrode of the second bare chip, an inner second Kelvin source contact for contacting a second Kelvin source electrode of the second bare chip, and an inner first drain contact for contacting a first drain electrode of the first bare chip.

6. The device of claim 5, wherein the first interposer further comprises an outer second drain contact for contacting a positive voltage (V+) contact in the main circuit, an outer first source contact for contacting a negative voltage (V−) contact in the main circuit, an outer first gate contact for contacting a PCB first gate contact in the main circuit, and an outer first Kelvin source contact for contacting a PCB first Kelvin source contact in the main circuit; and
wherein the first interposer further comprises a plurality of first through-vias for connecting the inner second drain contact to the outer second drain contact, the inner first source contact to the outer first source contact, the inner first gate contact to the outer first gate contact, and the inner first Kelvin source contact to the outer first Kelvin source contact.

7. The device of claim 5, wherein the second interposer further comprises an end first drain contact for contacting a PCB AC voltage contact in the main circuit, an end second gate contact for contacting a PCB second gate contact, and an end second Kelvin source contact for contacting a PCB second Kelvin source contact in the main circuit; and
wherein the second interposer further comprises a plurality of second through-vias for connecting each of the inner second source contact and the inner first drain contact with the PCB AC voltage contact via one of the outer conductors, to connect the inner second gate contact with the end second gate contact, and to connect the inner second Kelvin source contact with the end second Kelvin source contact via another one of the conductors of the second interposer.

8. The device of claim 1, wherein at least the first bare chip comprises a wide bandgap (WBG) power device.

9. The device of claim 8, wherein at least the first bare chip is a gallium nitride (GaN) field-effect transistor (FET) or a silicon carbide (SiC) metal-oxide-semiconductor field-effect transistor (MOSFET).

10. The device of claim 9, wherein the second bare chip is a FET functioning as a transistor or as a diode.

11. The device of claim 1, wherein the main circuit comprises at least a decoupling capacitor, a load inductor, and a bank capacitor.

12. A system for testing characteristics of the DUT, the system comprising:
the device of claim 1;
a test fixture configured to mount the device; and
a pressing force assembly configured to apply the pressing force to the at least one pressing plate, which transfers the pressing force to the second interposer.

13. The system of claim 12, wherein the pressing force assembly comprises:
a frame;
a plurality of fasteners configured to physically attach the frame to the test fixture or the main PCB; and
at least one set screw passing through the frame and configured to apply the pressing force to the at least one pressing plate upon operation.

14. A device for testing characteristics of a device under test (DUT), the DUT being a first bare chip, the device comprising:
a main printed circuit board (PCB) comprising a main circuit;
a first interposer arranged on a surface of the main PCB;
a second interposer arranged over the first interposer and the surface of the main PCB, wherein the first bare chip is arranged between the second interposer and the first interposer in a first orientation for testing of the first bare chip, and a second bare chip is arranged between the second interposer and the first interposer in a second orientation for the testing of the first bare chip, wherein the second orientation is opposite the first orientation; and
at least one pressing plate configured to apply a pressing force against the second interposer for pressing the second interposer toward the first interposer and the main PCB to enhance electrical connections between each of the first and second bare chips and the first interposer, between each of the first and second bare chips and the second interposer, and between each of the first and second interposers and the main PCB.

15. The device of claim 14, further comprising:
a plurality of alignment pins configured to align the main PCB, the first interposer, and the second interposer in a vertical direction for the testing of the first bare chip.

16. The device of claim 14, wherein the first bare chip is a first field effect transistor (FET) and the second bare chip is a second FET,
wherein the first FET is arranged in the first orientation between the second interposer and the first interposer such a first drain electrode of the first FET is in contact with the second interposer, and a first source electrode, a first gate electrode and a first Kelvin source electrode of the first FET are in contact with the first interposer for the testing of the first FET, and
wherein the second FET is arranged in the second orientation between the second interposer and the first interposer such a second drain electrode of the second FET is in contact with the first interposer, and a second source electrode, a second gate electrode and a second Kelvin source electrode of the second FET are in contact with the second interposer for the testing of the first FET.

17. The device of claim 14, wherein each of the first interposer and the second interposer comprises a flexible substrate.

18. The device of claim 17, wherein the second interposer includes outer conductors on an outer surface, facing away from the first and second bare chips,
wherein the outer conductors electrically connect the first and second bare chips to the main circuit, and
wherein the flexible substrate of the second interposer acts as an insulator and enhances insulation voltage between the outer conductors on the outer surface of the second interposer and each of the first bare chip, the second bare chip, and the main circuit.

19. The device of claim 14, wherein the first bare chip is a gallium nitride (GaN) field-effect transistor (FET) or a silicon carbide (SiC) metal-oxide-semiconductor field-effect transistor (MOSFET), and wherein the second bare chip is a FET functioning as a transistor or as a diode.

20. A method for testing a device under test (DUT), the method comprising:
arranging a first interposer on a surface of a main printed circuit board (PCB) comprising a main circuit;
arranging a first bare chip and a second bare chip on a surface of the first interposer, wherein the first bare chip is the DUT, wherein the first interposer provides first electrical connections with the first bare chip, the second bare chip, and the main circuit by contact, without soldering;
arranging a second interposer arranged over the first bare chip, the second bare chip, the first interposer and the main PCB, such that the first bare chip and a second bare chip are between the second interposer and the first interposer for testing of the first bare chip, wherein the second interposer is configured to provide second electrical connections with the first bare chip, the second bare chip, and the main circuit by contact, without soldering;
arranging at least one pressing plate on at least one portion of the second interposer;
applying a pressing force to the pressing plate for pressing the second interposer toward the first interposer and the main PCB, wherein the pressing force enhances the first and second electrical connections; and
testing at least one characteristic of the first bare chip while applying the pressing force against the second interposer.
